(19) United States
(12) Patent Application Publication
(10) Pub. No.: US 2025/0253199 A1
(43) Pub. Date: Aug. 7, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Li-Hsien Huang, Hsinchu (TW); Jyun-Yang Wang, Hsinchu (TW); Yao-Chun Chuang, Hsinchu (TW); Syu-Fong Li, Hsinchu (TW); Chih-Mu Huang, Hsinchu (TW)

(73) Assignee: Taiwan Semiconductor Manufacturing Company, Ltd., Hsinchu (TW)

(21) Appl. No.: 18/433,934

(22) Filed: Feb. 6, 2024

(51) Int. Cl. H01L 23/31; H01L 21/56; H01L 23/00; H01L 25/00; H01L 25/065

(52) U.S. Cl. CPC H01L 23/3192; H01L 21/561; H01L 23/3171; H01L 23/3185; H01L 25/0657; H01L 25/50; H01L 24/05; H01L 24/08; H01L 24/13; H01L 24/32; H01L 2224/0557; H01L 2224/08145; H01L 2224/13021; H01L 2224/32221

(57) ABSTRACT

A semiconductor device includes a first semiconductor chip, a second semiconductor chip and a filling layer. The first semiconductor chip has a first lateral surface and includes a first oxide layer, a debris layer and a silicon nitride layer. The first oxide layer is exposed from the first lateral surface. The silicon nitride layer is exposed from the first lateral surface and located between the first oxide layer and the debris layer. The second semiconductor chip is disposed on the first semiconductor chip and has a second lateral surface. The filling layer is disposed on the first semiconductor chip and the second lateral surface of the second semiconductor chip.

### BACKGROUND

Laser grooving (LGV) followed with mechanical saw need to be applied in a singulation for a conventional semiconductor device. The laser grooving process is hard to control because a GFOx (gap-fill oxide) does not absorb an ultraviolet (UV) laser, and thus it causes peeling or metal residue after the laser grooving.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a semiconductor device in an embodiment of the present disclosure; and

FIGS. 2A to 2S illustrate schematic diagrams of manufacturing processes of the semiconductor device in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

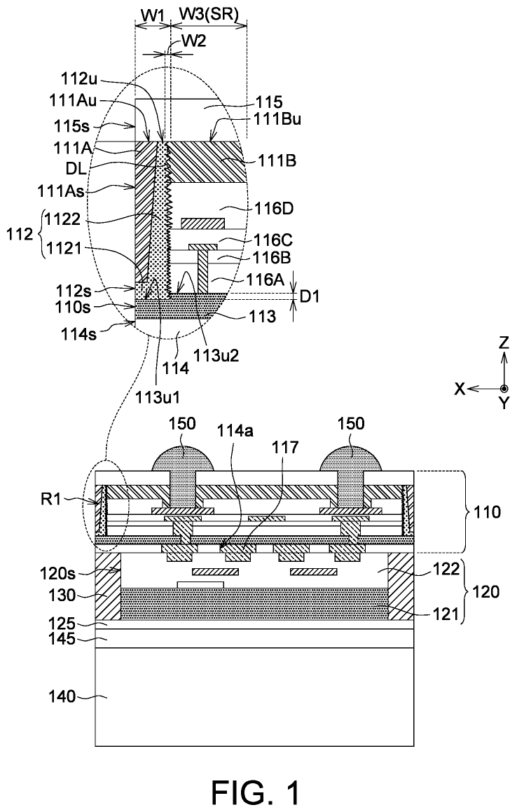

Referring to FIG. 1, FIG. 1 illustrates a schematic diagram of a semiconductor device 100 in an embodiment of the present disclosure. The semiconductor device 100 is, for example, a SoIC (System of Integrated Chips-Chip)-CoW (Chip on Wafer), SoIC-WOW (Wafer on Wafer), etc.

As illustrated in FIG. 1, the semiconductor device 100 includes a first semiconductor chip 110, a second semiconductor chip 120, a bonding layer 125, a filling layer 130, a carrier 140, a bonding layer 145 and at least one contact 150. The first semiconductor chip 110 has a first lateral surface 110s and includes a first oxide layer 111A, a second oxide layer 111B, a silicon nitride (SiN) layer 112 and a debris layer DL, a first silicon substrate 113, a dielectric layer 114, a dielectric layer 115, a BEOL structure 116 and a conductive layer 117.

As illustrated in FIG. 1, the first oxide layer 111A is exposed from the first lateral surface 110s. The silicon nitride layer 112 is exposed from the first lateral surface 110s and located between the first oxide layer 111A and the debris layer DL. The second semiconductor chip 120 is disposed on the first semiconductor chip 110 and has a second lateral surface 120s. The filling layer 130 is disposed on the first semiconductor chip 110 and the second lateral surface 120s of the second semiconductor chip 120.

As illustrated in FIG. 1, the first oxide layer 111A, the silicon nitride layer 112 and the debris layer DL form a sandwich structure. The sandwich structure is used to improve the device sidewall singulation for better reliability performance by mechanical saw. In another embodiment, the first oxide layer 111A may be removed in a singulation process.

As illustrated in FIG. 1, the first oxide layer 111A further has a first upper surface 111Au, the silicon nitride layer 112 has a second upper surface 112u, and the first upper surface 111Au and the second upper surface 112u are flushed with each other by a CMP (Chemical-Mechanical Polishing) process. In addition, the second oxide layer 111B has a third upper surface 111Bu. The first upper surface 111Au, the second upper surface 112u and the third upper surface 111Bu are flushed with each other by the CMP process.

As illustrated in FIG. 1, the first oxide layer 111A has a first sub-lateral surface 111As, and the silicon nitride layer 112 has a second sub-lateral surface 112s. The first sub-lateral surface 111As and the second sub-lateral surface 112s are flushed with each other by a sawing process. In another embodiment, the first sub-lateral surface 111As, the second sub-lateral surface 112s and the first lateral surface 110s are flushed with each other by the sawing process. In addition, the dielectric layer 114 has a lateral surface 114s, wherein the first sub-lateral surface 111As, the second sub-lateral surface 112s, the first lateral surface 110s and the lateral surface 114s are flushed with each other by the sawing process.

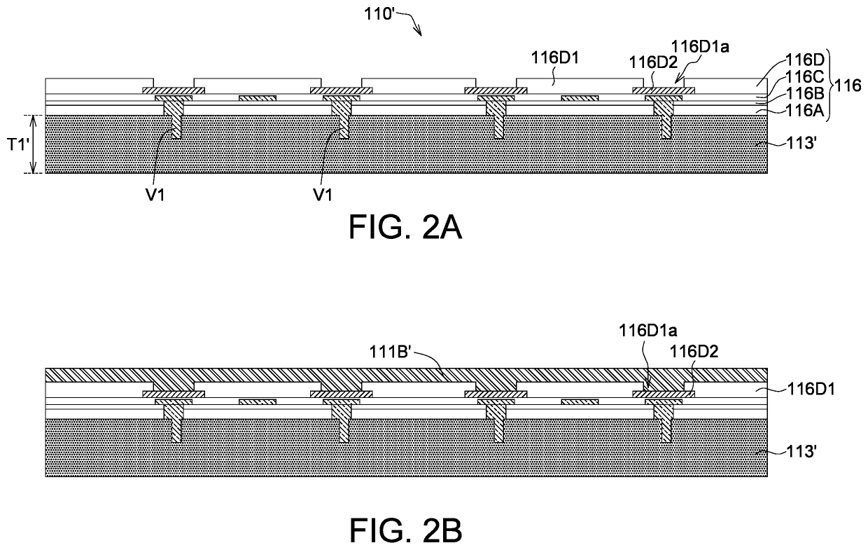

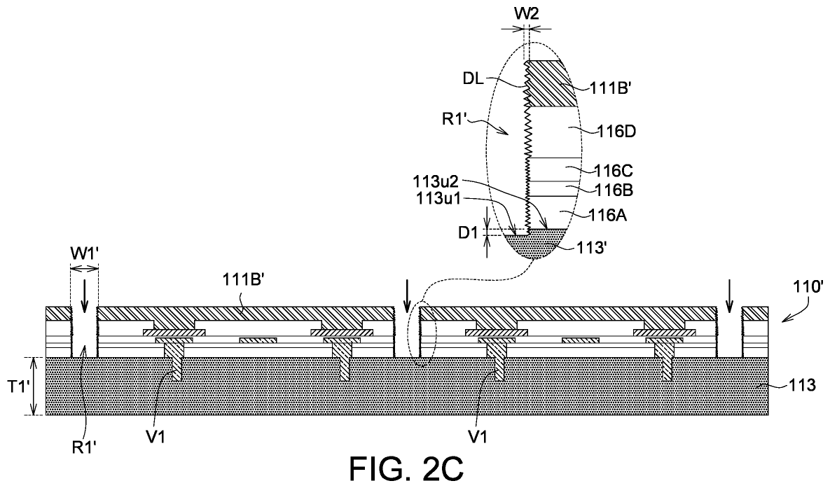

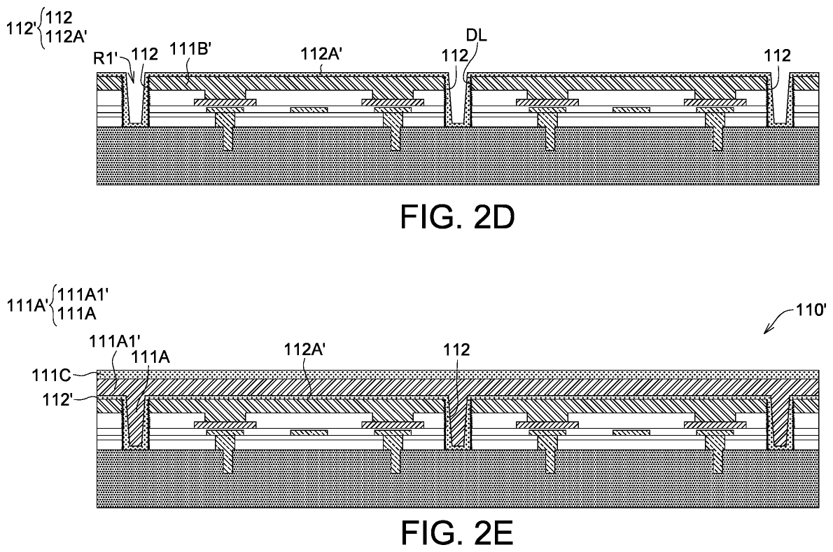

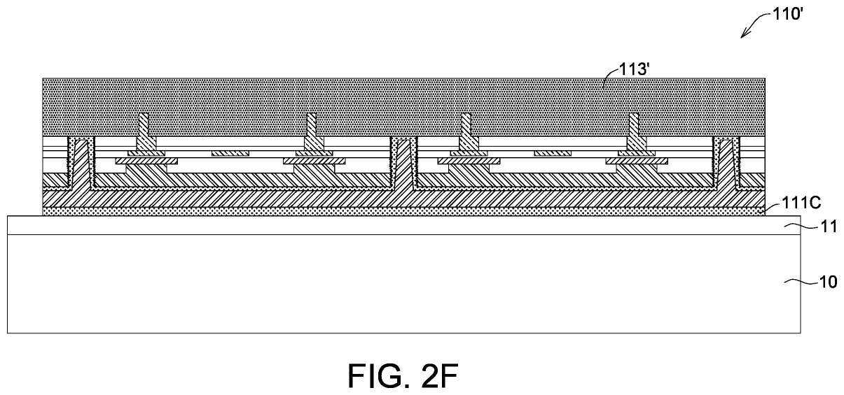

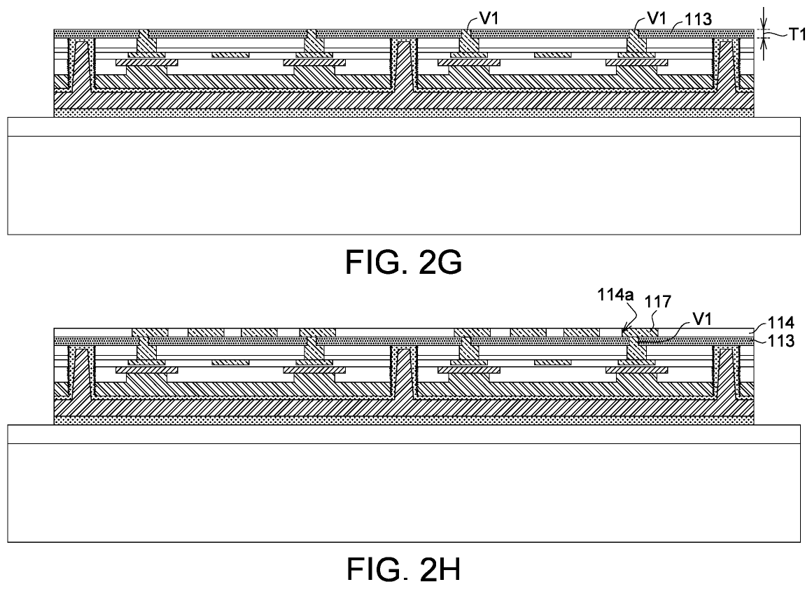

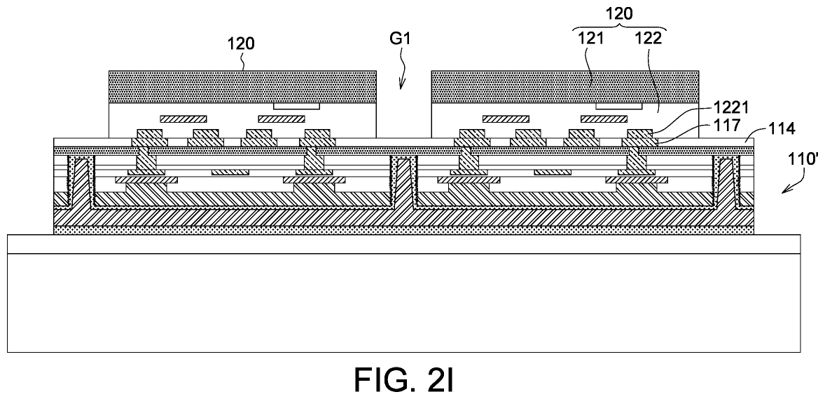

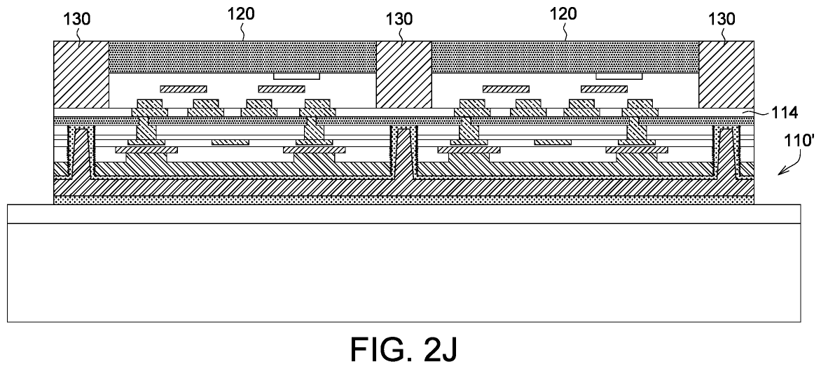

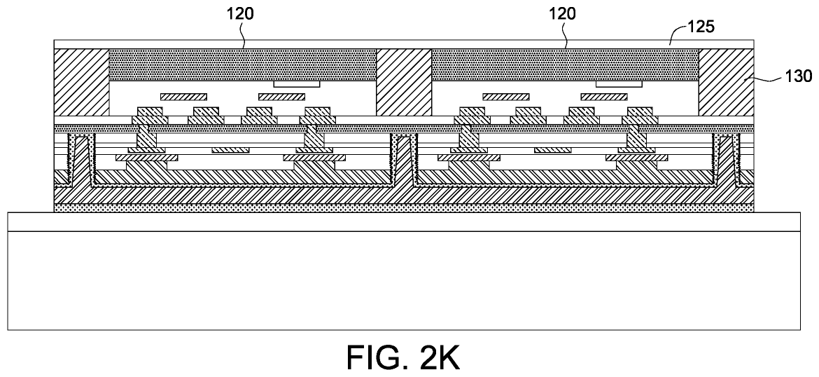

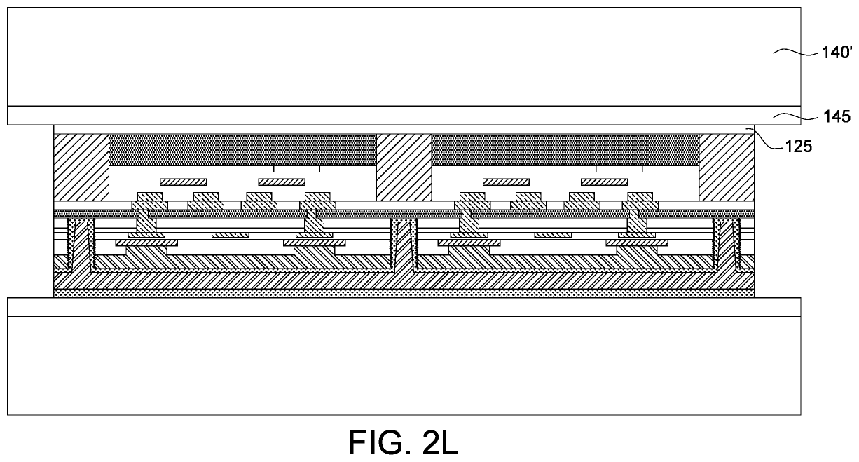

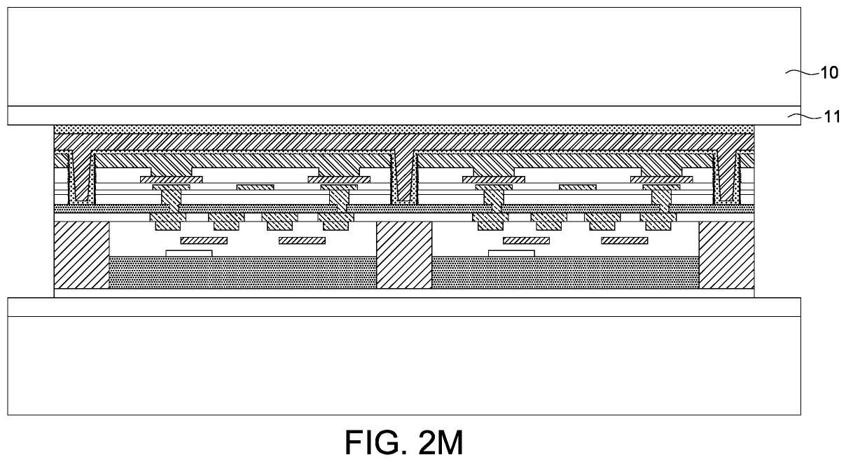

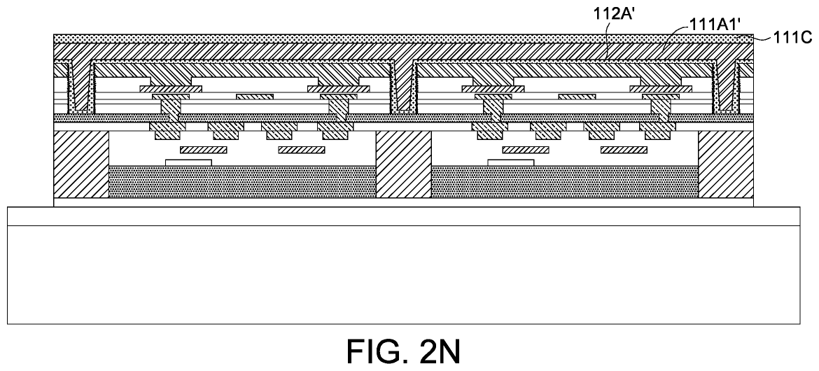

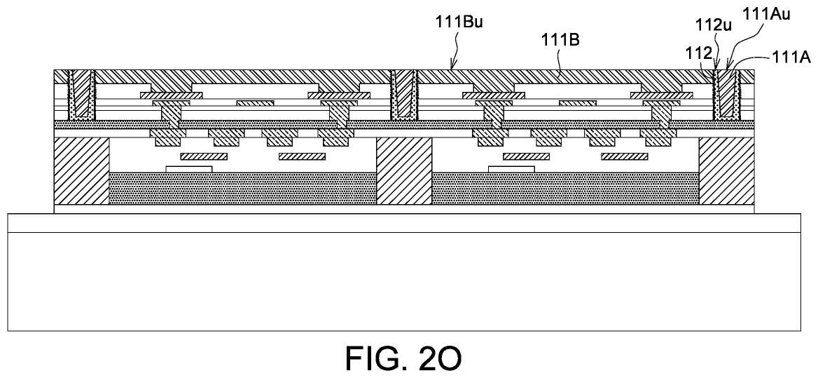

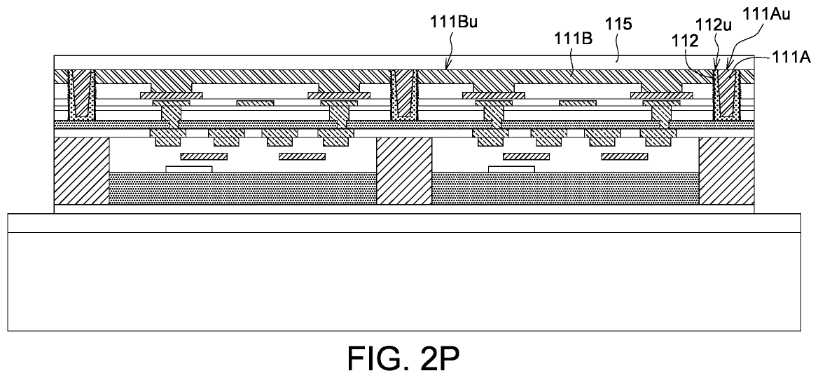

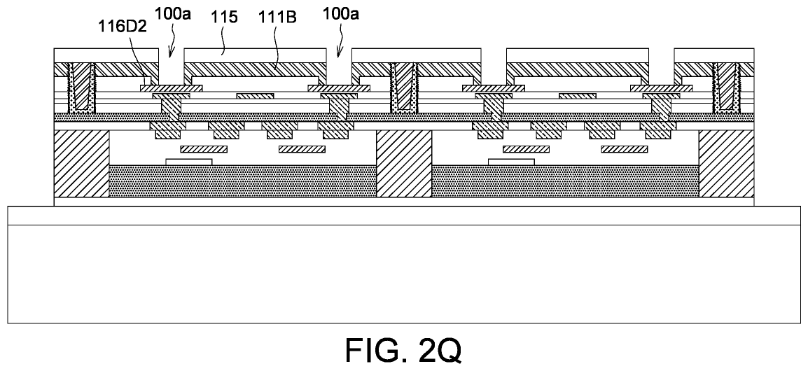

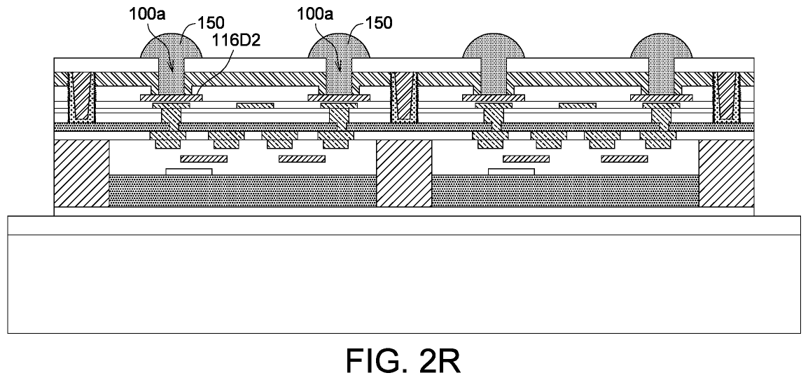

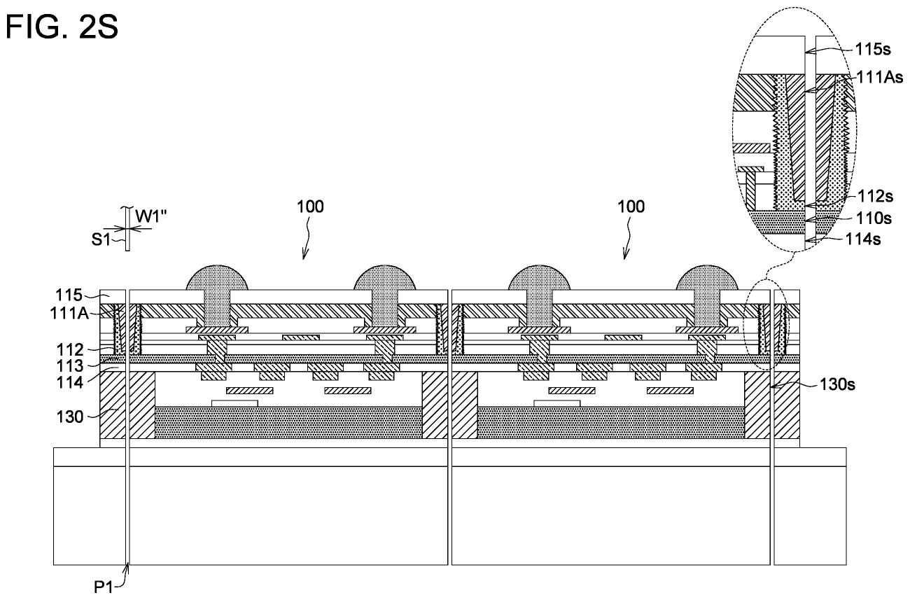

As illustrated in FIG. 1, the silicon nitride layer 112 includes a first portion 1121 and a second portion 1122 connected with the first portion 1121. The first portion 1121 extends in a first direction X, and the second portion 1122 extends in a second direction Y perpendicular to the first direction X. The silicon nitride layer 112 may be formed after the debris layer DL, and thus the silicon nitride layer 112 may cover at least one portion of the debris layer DL (see FIG. 2D).

As illustrated in FIG. 1, the first silicon substrate 113 of the first semiconductor chip 110 has the first lateral surface 110s as aforementioned above. The first silicon substrate 113 is, for example, a portion of a silicon wafer. Although not illustrated, the first silicon substrate 113 may include a FEOL (Front End of Line) structure (not illustrated) at least including at least one transistor. In addition, the first silicon substrate 113 has a first upper surface 113u1 and a second upper surface 113u2. There is a distance D1 between the second upper surface 113u2 and the first upper surface 113u1 in the third direction Z, wherein the distance D1 ranges between 0 μm and 60 μm, or 7 μm and 60 μm.

As illustrated in FIG. 1, the dielectric layer 114 is formed on the first silicon substrate 113 and has a plurality of openings 114a. The conductive layer 117 is formed within the openings 114a. The conductive layer 117 may include at least one conductive pad and/or at least one conductive trace which is electrically with the FEOL structure (not illustrated) of the first silicon substrate 113.

As illustrated in FIG. 1, the dielectric layer 115 covers the first upper surface 111Au of the first oxide layer 111A, the second upper surface 112u of the silicon nitride layer 112 and the third upper surface 111Bu of the second oxide layer 111B. The dielectric layer 115 has a lateral surface 115s, wherein the first sub-lateral surface 111As, the second sub-lateral surface 112s, the first lateral surface 110s, the lateral surface 114s and the lateral surface 115s are flushed with each other by the sawing process. In addition, the dielectric layer 115 may be, for example, a high temperature (HT) SiN film.

As illustrated in FIG. 1, the debris layer DL is formed on lateral surfaces of the second oxide layer 111B, the BEOL structure 116 and the first silicon substrate 113 in a laser grooving (LGV) process. The semiconductor device 100 further includes at least one recess R1 which is formed by the laser grooving process. The recess R1 extends to the debris layer DL from the first lateral surface 110s in the first direction X, and extends to a first upper surface 113u1 from the third upper surface 111Bu of the second oxide layer 111B in a third direction Z. The recess R1 has a first width W1 ranging between, for example, 30 micrometers (μm) and 400 μm, even less or even greater.

As illustrated in FIG. 1, the BEOL structure 116 includes, for example, a first structure layer 116A, a second structure layer 116B, a third structure layer 116C and a fourth dielectric layer 116D. The debris layer DL may be formed on the lateral surfaces of the first structure layer 116A, the second structure layer 116B, the third structure layer 116C and the fourth dielectric layer 116D. In another embodiment, the semiconductor device 100 may omit the debris layer DL.

As illustrated in FIG. 1, the first structure layer 116A is formed between the first silicon substrate 113 and the second structure layer 116B. Each of the structure layers 116A and 116B may include a conductive layer (for example, including at least conductive pad and/or at least one conductive via) and a dielectric layer, wherein the conductive layer is formed in/on the dielectric layer. The dielectric layer of the first structure layer 116A and the dielectric layer of the second structure layer 116B may be formed of a material including, for example, an extreme low-K (ELK) dielectric material. Each of the structure layers 116C and 116D may include a conductive layer (for example, including at least conductive pad and/or at least one conductive via) and an oxide layer, wherein the conductive layer is formed in/on the oxide layer. The conductive layer may be formed of a material including a metal, for example, copper, etc.

The mechanicalness of ELK material is inferior to silicon dioxide. Compare with silicon dioxide, the ELK material is more fragile. Thus, the ELK dielectric material can't be processed by the sawing. In an embodiment, the ELK dielectric material may be processed by the laser grooving process. After the laser cutting for the second oxide layer 111B, the fourth structure layer 116D, the structure layer 116C, the second structure layer 116B and the first dielectric layer 116A, the debris layer DL is formed on the lateral surfaces of the second oxide layer 111B, the structure layer 116D, the third structure layer 116C, the second structure layer 116B, the first dielectric layer 116A and the first silicon substrate 113.

As illustrated in FIG. 1, the semiconductor device 100 includes a seal ring SR. The seal ring SR has a third width W3 ranging between, for example, 20 nanometer (nm) and 60 nm. The seal ring SR includes an edge portion of the BEOL structure 116, an edge portion of the second oxide layer 111B and an edge portion of the dielectric layer 115. The seal ring SR includes at least one conductive layer (for example, dummy conductive pad, conductive via, etc.) for increasing the strength of the semiconductor device 100.

As illustrated in FIG. 1, the second semiconductor chip 120 is located between the first semiconductor chip 110 and the carrier 140. The second semiconductor chip 120 includes a second silicon substrate 121 and a structure layer 122. The second silicon substrate 121 is, for example, a portion of silicon wafer. The structure layer 122 may include a conductive layer (for example, including at least conductive pad and/or at least one conductive via) and a dielectric layer, wherein the conductive layer is formed in/on the dielectric layer.

As illustrated in FIG. 1, the carrier 140 and the second semiconductor chip 120 may be combined through the bonding layer 145 and the bonding layer 125. In an embodiment, the bonding layer 125 may be pre-formed on the second semiconductor chip 120, and the bonding layer 145 may be pre-formed on the carrier 140, and then the carrier 140 and the second semiconductor chip 120 may be combined through the bonding layer 145 and the bonding layer 125.

As illustrated in FIG. 1, the contact 150 is, for example, a solder ball, a conductive bump, a conductive pillar, etc. The semiconductor device 100 may be disposed on and electrically connected with an electronic component, for example, a circuit board, a semiconductor chip, a semiconductor package, etc.

Referring to FIGS. 2A to 2S, FIGS. 2A to 2S illustrate schematic diagrams of manufacturing processes of the semiconductor device 100 in FIG. 1.

As illustrated in FIG. 2A, the first semiconductor structure 110′ is provided. The first semiconductor structure 110′ includes a first silicon substrate 113′ and the BEOL structure 116 formed on the first silicon substrate 113′. Although not illustrated, the first semiconductor structure 110′ further includes a FEOL structure formed within the first silicon substrate 113′. The FEOL structure includes at least one transistor (not illustrated). The first semiconductor structure 110′ further includes at least one conductive via V1 formed within the first silicon substrate 113′, but not passing through the first silicon substrate 113′. The conductive via V1 is, for example, a TSV (through-silicon via). The first silicon substrate 113′ has a thickness T1′ of about 775 μm.

In FIG. 2A, the BEOL structure 116 includes the first structure layer 116A, the second structure layer 116B, the third structure layer 116C and the fourth structure layer 116D, wherein the first structure layer 116A is formed between the first silicon substrate 113′ and the second structure layer 116B, the second structure layer 116B is formed between the first structure layer 116A and the third structure layer 116C, the third structure layer 116C is formed between the second structure layer 116B and the fourth structure layer 116D. The fourth structure layer 116D includes the oxide layer 116D1 and a conductive layer 116D2 (including at least conductive pad and/or at least one conductive via), wherein the oxide layer 116D1 has at least one opening 116D1a exposing the conductive layer 116D2. The opening 116D1a may be formed by, for example, lithography (including exposure, development and etching), etc.

As illustrated in FIG. 2B, a second oxide layer material 111B′ is formed by using, for example, deposition, etc. The second oxide layer material 111B′ fills the opening 116D1a and covers the oxide layer 116D1. In addition, the second oxide layer material 111B′ may be planarized by using, for example, CMP. In addition, the second oxide layer material 111B′ is, for example, a TEOS (tetraethoxysilane) oxide material. Furthermore, the second oxide layer material 111B′ may be formed by deposition in a TEOS atmosphere.

As illustrated in FIG. 2C, at least one recess R1′ passing through the second oxide layer material 111B′, the fourth structure layer 116D, the third structure layer 116C, the second structure layer 116B, the first structure layer 116A and a portion of the first silicon substrate 113′ is formed by using, for example, the LGV process. In the present embodiment, the LGV is not applied to the filling layer 130 (which is formed in subsequent process of FIG. 2J), and thus it may prevent from peeling or metal residue after the laser grooving.

In FIG. 2C, after LGV process, the first silicon substrate 113′ forms the second upper surface 113u2, wherein there is the distance D1 between the second upper surface 113u2 and the first upper surface 113u1 in the third direction Z, and the distance D1 may range between 7 μm and 60 μm. In addition, due to the first silicon substrate 113′ in FIG. 2C being thick enough, even if the first silicon substrate 113′ is overcut by the recess R1′, the first silicon substrate 113′ will not be cut off. In addition, the recess R1′ has a recess width W1′ greater the first width W1 of FIG. 1.

In FIG. 2C, after LGV process, the debris layer DL is formed on the lateral surfaces of the second oxide layer material 111B′, the structure layer 116D, the third structure layer 116C, the second structure layer 116B, the first dielectric layer 116A and the first silicon substrate 113′. The debris layer DL has the second width W2 ranging between, for example, 0 and 5 μm, such as 0 μm, 1 μm, 2 μm, 3 μm, 4 μm or 5 μm.

As illustrated in FIG. 2D, a silicon nitride layer material 112′ is formed by using, for example, deposition, etc. The silicon nitride layer material 112′ includes a portion 112A′ and the silicon nitride layer 112, wherein the portion 112A′ covers an upper surface of the second oxide layer material 111B′, and the silicon nitride layer 112 covers a sidewall of the recess R1′. In addition, the silicon nitride layer material 112′ is, for example, a low-temperature (LT) SiN film.

As illustrated in FIG. 2E, a first oxide layer material 111A′ covering the silicon nitride layer material 112′ is formed by using, for example, deposition, etc. The first oxide layer material 111A′ is, for example, a TEOS oxide material. Furthermore, the first oxide layer material 111A′ may be formed by deposition in a TEOS atmosphere. The first oxide layer material 111A′ includes a portion 111A1′ and the first oxide layer 111A, wherein the portion 111A1′ covers the portion 112A′, and the first oxide layer 111A covers the silicon nitride layer 112. The first oxide layer material 111A′ and the silicon nitride layer material 112′ fill the entirety of the recess R1′. Furthermore, the first oxide layer 111A and the silicon nitride layer 112 fill the entirety of the recess R1′.

Then, a USG (undoped silicate glass) layer 111C covering the first oxide layer material 111A′ is formed by using, for example, deposition, etc. In an embodiment, the silicon nitride layer material 112′, the first oxide layer material 111A′ and the USG layer 111C may be called a “bonding film”. Then, the USG layer 111C may be planarized by using, for example, CMP.

As illustrated in FIG. 2F, the first semiconductor structure 110′ may be inverted and then be bonded to a first carrier 10 through a bonding layer 11. The bonding layer 11 may be pre-formed on the first carrier 10. In addition, the bonding layer 11 may be formed of, for example, oxide, and the first carrier 10 may be formed of, for example, silicon.

As illustrated in FIG. 2G, the first silicon substrate 113′ in FIG. 2F may be thinned by using, for example, CMP, to form the first silicon substrate 113 as illustrated in FIG. 1. After CMP, the first silicon substrate 113 has a thickness T1 ranging between, for example, 5 μm and 9 μm, such as 5 μm, 6 μm, 7 μm, 8 μm or 9 μm. In addition, After CMP, the conductive via V1 is exposed.

As illustrated in FIG. 2H, the dielectric layer 114 covering the first silicon substrate 113 and having at least one opening 114a is formed by using, for example, deposition and lithography (including exposure, development and etching), etc. The conductive via V1 is exposed from the opening 114a. Then, the conductive layer 117 may be formed within the opening 114a and connected with the exposed conductive via V1 by using, for example, deposition or plating.

As illustrated in FIG. 2I, at least one second semiconductor chip 120 is disposed on and electrically connected with the first semiconductor structure 110′. The second semiconductor chip 120 includes the second silicon substrate 121 and a structure layer 122. The structure layer 122 may include a conductive layer 1221 (including at least conductive pad and/or at least one conductive via) and a dielectric layer, wherein the conductive layer is formed in/on the dielectric layer. The conductive layer 1221 of the second semiconductor chip 120 faces and is electrically connected with the conductive layer 117 of the first semiconductor structure 110′. In addition, there is at least one gap G1 between the adjacent two second semiconductor chips 120.

As illustrated in FIG. 2J, the filling layer 130 filling the gap G1 and surrounding the second semiconductor chip 120 is formed by using, for example, PECVD (Plasma-enhanced chemical vapor deposition), etc. The filling layer 130 is also called gap-fill oxide (GFOx), and it may be formed of a material including, for example, a silicon dioxide, TEOS oxide material, etc.

As illustrated in FIG. 2K, the bonding layer 125 is formed on or above the filling layer 130 and the second semiconductor chips 120. The bonding layer 125 may be formed of, for example, oxide.

As illustrated in FIG. 2L, a second carrier 140′ is formed on the bonding layer 125 through the bonding layer 145. In an embodiment, the bonding layer 145 may be pre-formed on the second carrier 140′. The second carrier 140′ may be formed of, for example, silicon.

As illustrated in FIG. 2M, the structure in FIG. 2L is inverted to make the first carrier 10 face upward.

As illustrated in FIG. 2N, the first carrier 10 and the bonding layer 11 in FIG. 2M may be removed by using, for example, CMP, etching, etc. After removing, the USG layer 111C is exposed.

As illustrated in FIG. 2O, the USG layer 111C, the portion 112A′ of the silicon nitride layer material 112′ and the portion 111A1′ of the first oxide layer material 111A′ are removed by using, for example, CMP, etching, etc. After removing, the first oxide layer 111A forms the first upper surface 111Au, the silicon nitride layer 112 forms the second upper surface 112u, and the second oxide layer 111B forms the third upper surface 111Bu, wherein the first upper surface 111Au of the first oxide layer 111A, the second upper surface 112u of the silicon nitride layer 112 and the third upper surface 111Bu of the second oxide layer 111B are flushed with each other.

As illustrated in FIG. 2P, the dielectric layer 115 covering the first upper surface 111Au of the first oxide layer 111A, the second upper surface 112u of the silicon nitride layer 112 and the third upper surface 111Bu of the second oxide layer 111B is formed by using, for example, deposition, etc.

As illustrated in FIG. 2Q, at least one opening 100a passing through the dielectric layer 115 and the second oxide layer 111B is formed by using, for example, lithography (including exposure, development and etching), etc. At least one portion of the conductive layer 116D2 is exposed from the opening 100a.

As illustrated in FIG. 2R, at least one contact 150 connected, through the opening 100a, with the exposed conductive layer 116D2 is formed.

As illustrated in FIG. 2S, at least one singulation passage P1 passing through the structure in FIG. 2R, by a machine tool SI (for example, a saw), to form at least one semiconductor device 100. In the present embodiment, the singulation in FIG. 2S may be completed by only sawing (that is, without LGV). In the present embodiment, the material which is passed through by the machine tool SI does not include the fragile ELK material. In FIG. 2S, the machine tool SI has a tool width W1″ less than the recess width W1′ in FIG. 2C. In an embodiment, the recess width W1′ is twice the tool width W1″, for example.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes the first oxide layer, the silicon nitride layer and the debris layer, wherein the first oxide layer and the silicon nitride layer are laterally exposed, and the silicon nitride layer is formed between the first oxide layer and the debris layer to form the sandwich structure.

In Example embodiment 1, a semiconductor device includes a first semiconductor chip, a second semiconductor chip and a filling layer. The first semiconductor chip has a first lateral surface and includes a first oxide layer, a debris layer and a silicon nitride layer. The first oxide layer is exposed from the first lateral surface. The silicon nitride layer is exposed from the first lateral surface and located between the first oxide layer and the debris layer. The second semiconductor chip is disposed on the first semiconductor chip and has a second lateral surface. The filling layer is disposed on the first semiconductor chip and the second lateral surface of the second semiconductor chip.

In Example embodiment 2, the first oxide layer has a first sub-lateral surface, the silicon nitride layer has a second sub-lateral surface, and the first sub-lateral surface and the second sub-lateral surface are flushed with each other.

In Example embodiment 3, the first semiconductor chip further includes a first silicon substrate having the first lateral surface; wherein the first oxide layer has a first sub-lateral surface, the silicon nitride layer has a second sub-lateral surface, and the first sub-lateral surface, the second sub-lateral surface and the first lateral surface are flushed with each other.

In Example embodiment 4, the silicon nitride layer includes a first portion extending in a first direction, and a second portion connected with the first portion and extending in a second direction perpendicular to the first direction.

In Example embodiment 5, the semiconductor device further includes a carrier, and the second semiconductor chip is located between the first semiconductor chip and the carrier.

In Example embodiment 6, the first oxide layer further has a first upper surface, the silicon nitride layer has a second upper surface, and the first upper surface and the second upper surface are flushed with each other.

In Example embodiment 7, the first semiconductor chip further includes a second oxide layer having a third upper surface, and the first upper surface, the second upper surface and the third upper surface are flushed with each other.

In Example embodiment 8, the semiconductor device further has a recess extending to the debris layer from the first lateral surface, and the first oxide layer and the silicon nitride layer are disposed within the recess.

In Example embodiment 9, the first semiconductor chip further includes a first silicon substrate having the first lateral surface, a second oxide layer, and a BEOL structure disposed between the first silicon substrate and the second oxide layer. The debris layer is disposed on lateral surfaces of the first silicon substrate, the second oxide layer and the BEOL structure.

In Example embodiment 10, a semiconductor device includes a first semiconductor chip, a second semiconductor chip and a filling layer. The first semiconductor chip has a first lateral surface and includes a first oxide layer and a silicon nitride layer. The first oxide layer is exposed from the first lateral surface. The silicon nitride layer is exposed from the first lateral surface. The second semiconductor chip is disposed on the first semiconductor chip and has a second lateral surface. The filling layer is disposed on the first semiconductor chip and the second lateral surface of the second semiconductor chip.

In Example embodiment 11, the first oxide layer has a first sub-lateral surface, the silicon nitride layer has a second sub-lateral surface, and the first sub-lateral surface and the second sub-lateral surface are flushed with each other.

In Example embodiment 12, the first semiconductor chip further includes a first silicon substrate having the first lateral surface; wherein the first oxide layer has a first sub-lateral surface, the silicon nitride layer has a second sub-lateral surface, and the first sub-lateral surface, the second sub-lateral surface and the first lateral surface are flushed with each other.

In Example embodiment 13, the silicon nitride layer includes a first portion extending in a first direction, and a second portion connected with the first portion and extending in a second direction perpendicular to the first direction.

In Example embodiment 14, the semiconductor device further includes a carrier, and the second semiconductor chip is located between the first semiconductor chip and the carrier.

In Example embodiment 15, the first oxide layer further has a first upper surface, the silicon nitride layer has a second upper surface, and the first upper surface and the second upper surface are flushed with each other.

In Example embodiment 16, the first semiconductor chip further includes a second oxide layer having a third upper surface, and the first upper surface, the second upper surface and the third upper surface are flushed with each other.

In Example embodiment 17, a manufacturing method for a semiconductor device includes the following steps: forming a debris layer on a first semiconductor chip by a laser grooving process; forming a silicon nitride layer over the debris layer; forming a first oxide layer over the silicon nitride layer, wherein the silicon nitride layer is located between the first oxide layer and the debris layer; disposing a second semiconductor chip on the first semiconductor chip, wherein the second semiconductor chip has a second lateral surface; forming a filling layer on the first semiconductor chip and the second lateral surface of the second semiconductor chip; and forming a singulation passage passing through the first oxide layer, the silicon nitride layer and the filling layer by a machine tool, wherein the silicon nitride layer is exposed from a first lateral surface of the first semiconductor chip.

In Example embodiment 18, in forming the singulation passage passing through the first oxide layer, the silicon nitride layer and the filling layer by the machine tool, the first oxide layer forms a first sub-lateral surface, the silicon nitride layer forms a second sub-lateral surface, and the first sub-lateral surface and the second sub-lateral surface are flushed with each other.

In Example embodiment 19, in forming the singulation passage passing through the first oxide layer, the silicon nitride layer and the filling layer by the machine tool, the singulation passage further passes through a first silicon substrate, the first silicon substrate forms the first lateral surface, the first oxide layer forms a first sub-lateral surface, the silicon nitride layer forms a second sub-lateral surface, and the first sub-lateral surface, the second sub-lateral surface and the first lateral surface are flushed with each other.

In Example embodiment 20, in forming the debris layer on the first semiconductor chip by the laser grooving process, the debris layer is formed on a first silicon substrate of the first semiconductor chip; before disposing the second semiconductor chip on the first semiconductor chip, the manufacturing method further includes: thinning the first silicon substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. cm What is claimed is:

1. A semiconductor device, comprising:
a first semiconductor chip having a first lateral surface and comprising:
a first oxide layer exposed from the first lateral surface;
a debris layer; and
a silicon nitride layer exposed from the first lateral surface and located between the first oxide layer and the debris layer;
a second semiconductor chip disposed on the first semiconductor chip and having a second lateral surface; and
a filling layer disposed on the first semiconductor chip and the second lateral surface of the second semiconductor chip.

2. The semiconductor device according to claim 1, wherein the first oxide layer has a first sub-lateral surface, the silicon nitride layer has a second sub-lateral surface, and the first sub-lateral surface and the second sub-lateral surface are flushed with each other.

3. The semiconductor device according to claim 1, wherein the first semiconductor chip further comprises:
a first silicon substrate having the first lateral surface;
wherein the first oxide layer has a first sub-lateral surface, the silicon nitride layer has a second sub-lateral surface, and the first sub-lateral surface, the second sub-lateral surface and the first lateral surface are flushed with each other.

4. The semiconductor device according to claim 1, wherein the silicon nitride layer comprises:
a first portion extending in a first direction; and
a second portion connected with the first portion and extending in a second direction perpendicular to the first direction.

5. The semiconductor device according to claim 1, further comprises:
a carrier;
wherein the second semiconductor chip is located between the first semiconductor chip and the carrier.

6. The semiconductor device according to claim 1, wherein the first oxide layer further has a first upper surface, the silicon nitride layer has a second upper surface, and the first upper surface and the second upper surface are flushed with each other.

7. The semiconductor device according to claim 6, wherein the first semiconductor chip further comprises:
a second oxide layer having a third upper surface;
wherein the first upper surface, the second upper surface and the third upper surface are flushed with each other.

8. The semiconductor device according to claim 1, wherein the semiconductor device further has a recess extending to the debris layer from the first lateral surface, and the first oxide layer and the silicon nitride layer are disposed within the recess.

9. The semiconductor device according to claim 1, wherein the first semiconductor chip further comprises:
a first silicon substrate having the first lateral surface;
a second oxide layer; and
a BEOL structure disposed between the first silicon substrate and the second oxide layer;
wherein the debris layer is disposed on lateral surfaces of the first silicon substrate, the second oxide layer and the BEOL structure.

10. A semiconductor device, comprising:
a first semiconductor chip having a first lateral surface and comprising:
a first oxide layer exposed from the first lateral surface; and
a silicon nitride layer exposed from the first lateral surface;
a second semiconductor chip disposed on the first semiconductor chip and having a second lateral surface; and
a filling layer disposed on the first semiconductor chip and the second lateral surface of the second semiconductor chip.

11. The semiconductor device according to claim 10, wherein the first oxide layer has a first sub-lateral surface, the silicon nitride layer has a second sub-lateral surface, and the first sub-lateral surface and the second sub-lateral surface are flushed with each other.

12. The semiconductor device according to claim 10, wherein the first semiconductor chip further comprises:
a first silicon substrate having the first lateral surface;
wherein the first oxide layer has a first sub-lateral surface, the silicon nitride layer has a second sub-lateral surface, and the first sub-lateral surface, the second sub-lateral surface and the first lateral surface are flushed with each other.

13. The semiconductor device according to claim 10, wherein the silicon nitride layer comprises:
a first portion extending in a first direction;
a second portion connected with the first portion and extending in a second direction perpendicular to the first direction.

14. The semiconductor device according to claim 10, further comprises:
a carrier;
wherein the second semiconductor chip is located between the first semiconductor chip and the carrier.

15. The semiconductor device according to claim 10, wherein the first oxide layer further has a first upper surface, the silicon nitride layer has a second upper surface, and the first upper surface and the second upper surface are flushed with each other.

16. The semiconductor device according to claim 15, wherein the first semiconductor chip further comprises:
a second oxide layer having a third upper surface; and
wherein the first upper surface, the second upper surface and the third upper surface are flushed with each other.

17. A manufacturing method for a semiconductor device, comprising:
forming a debris layer on a first semiconductor chip by a laser grooving (LGV) process;
forming a silicon nitride layer over the debris layer;
forming a first oxide layer over the silicon nitride layer, wherein the silicon nitride layer is located between the first oxide layer and the debris layer;
disposing a second semiconductor chip on the first semiconductor chip, wherein the second semiconductor chip has a second lateral surface;
forming a filling layer on the first semiconductor chip and the second lateral surface of the second semiconductor chip; and
forming a singulation passage passing through the first oxide layer, the silicon nitride layer and the filling layer by a machine tool, wherein the silicon nitride layer is exposed from a first lateral surface of the first semiconductor chip.

18. The manufacturing method according to claim 17, wherein in forming the singulation passage passing through the first oxide layer, the silicon nitride layer and the filling layer by the machine tool, the first oxide layer forms a first sub-lateral surface, the silicon nitride layer forms a second sub-lateral surface, and the first sub-lateral surface and the second sub-lateral surface are flushed with each other.

19. The manufacturing method according to claim 17, wherein in forming the singulation passage passing through the first oxide layer, the silicon nitride layer and the filling layer by the machine tool, the singulation passage further passes through a first silicon substrate, the first silicon substrate forms the first lateral surface, the first oxide layer forms a first sub-lateral surface, the silicon nitride layer forms a second sub-lateral surface, and the first sub-lateral surface, the second sub-lateral surface and the first lateral surface are flushed with each other.

20. The manufacturing method according to claim 17, wherein in forming the debris layer on the first semiconductor chip by the laser grooving process, the debris layer is formed on a first silicon substrate of the first semiconductor chip; before disposing the second semiconductor chip on the first semiconductor chip, the manufacturing method further comprising:
thinning the first silicon substrate.
